(19) United States
(12) Patent Application Publication
(10) Pub. No.: US 2011/0178740 A1
(43) Pub. Date: Jul. 21, 2011

(54) METHOD OF STORING EVALUATION RESULT, METHOD OF DISPLAYING EVALUATION RESULT, AND EVALUATION RESULT DISPLAY DEVICE

(76) Inventor: Kazusuke KATOU, Miyazaki (JP)

(21) Appl. No.: 13/006,600

(22) Filed: Jan. 14, 2011

(30) Foreign Application Priority Data
Jan. 15, 2010 (JP) 2010-006957

(51) Int. Cl. G06F 19/00; G01R 31/26

(52) U.S. Cl. 702/58

(57) ABSTRACT

A method of storing an evaluation result includes the steps of: changing a first physical value related to a transistor constituting a semiconductor integrated circuit; changing a second physical value; measuring a deterioration value of reliability of the transistor with time according to the first physical value and the second physical value through a reliability evaluation; dividing the deterioration value into a plurality of continuous regions with a value of a predetermined range from a minimum deterioration value to a maximum deterioration value to obtain divided deterioration values; dividing the first physical value into a plurality of continuous regions with a value of a predetermined range; dividing the second physical value into a plurality of continuous regions with a value of a predetermined range; and storing the divided deterioration values in a storage unit according to the continuous regions of the first physical value and the second physical value.

### BACKGROUND OF THE INVENTION AND RELATED ART STATEMENT

The present invention relates to a method of storing an evaluation result, a method of displaying an evaluation result, and an evaluation result display device. In particular, the present invention relates to a method of storing an evaluation result obtained from a reliability evaluation, in which reliability of a transistor constituting a semiconductor integrated circuit with time is evaluated.

In a field effect transistor constituting a semiconductor integrated circuit, especially when a structure thereof is minimized, reliability thereof may be deteriorated with time due to factors such as insulation breakdown of an oxide film, a hot carrier phenomenon, an NBTI (Negative Bias Temperature Instability) phenomenon, and the like. Accordingly, the reliability of the transistor with time has been evaluated.

In the evaluation, a hot carrier life of an MOS transistor may be determined through extrapolating from a measurement value at a high drain voltage. Patent Reference has been disclosed a reliability evaluation method of a semiconductor element in order to minimize a variance of an extrapolated value.

Patent Reference: Japanese Patent Publication No. 05-226444

In the reliability evaluation method disclosed in Patent Reference, a plurality of MOS transistors having an identical channel length is arranged in a measurement region. Then, a measurement device concurrently performs a probing relative to the MOS transistors, so that the measurement device concurrently measures the hot carrier life of each of the MOS transistors under a plurality of drain voltages. Then, under a drain voltage smaller than any of the drain voltages, the hot carrier life is extrapolated from the hot carrier life of each of the MOS transistors thus measured under the drain voltages.

In the reliability evaluation method disclosed in Patent Reference, an evaluation result is displayed in a graph having a horizontal axis representing a board current per unit gate and a vertical axis representing the hot carrier life. In another conventional reliability evaluation method, an evaluation result is displayed only in a text. Accordingly, for a designer of a semiconductor integrated circuit, it is difficult to easily determine whether the semiconductor integrated circuit thus designed possesses desired reliability with time.

In view of the problems described above, an object of the present invention is to provide a method of storing an evaluation result, a method of displaying an evaluation result, and an evaluation result display device. In the present invention, it is possible to easily determine whether a semiconductor integrated circuit thus designed possesses desired reliability with time.

Further objects and advantages of the invention will be apparent from the following description of the invention.

### SUMMARY OF THE INVENTION

In order to attain the objects described above, according to a first aspect of the present invention, a method of storing an evaluation result includes the steps of: changing a first physical value specified in advance and related to a transistor constituting a semiconductor integrated circuit; changing a second physical value different from the first physical value; measuring a deterioration value of reliability of the transistor with time according to the first physical value and the second physical value through a reliability evaluation; dividing the deterioration value of the reliability of the transistor thus measured through the reliability evaluation into a plurality of continuous regions with a value of a predetermined range from a minimum deterioration value to a maximum deterioration value to obtain divided deterioration values; dividing the first physical value into a plurality of continuous regions with a value of a predetermined range; dividing the second physical value into a plurality of continuous regions with a value of a predetermined range; and storing the divided deterioration values in a storage unit according to the continuous regions of the first physical value and the continuous regions of the second physical value.

As described above, in the first aspect of the present invention, the method of storing the evaluation result includes the steps of dividing the deterioration value of the reliability of the transistor thus measured through the reliability evaluation into the continuous regions with the value of the predetermined range from the minimum deterioration value to the maximum deterioration value to obtain divided deterioration values; dividing the first physical value into the continuous regions with the value of the predetermined range; dividing the second physical value into the continuous regions with the value of the predetermined range; and storing the divided deterioration values in the storage unit according to the continuous regions of the first physical value and the continuous regions of the second physical value. Accordingly, it is possible to easily determine whether the semiconductor integrated circuit thus designed possesses desired reliability with time.

According to a second aspect of the present invention, a method of displaying an evaluation result includes the steps of: changing a first physical value specified in advance and related to a transistor constituting a semiconductor integrated circuit; changing a second physical value different from the first physical value; measuring a deterioration value of reliability of the transistor with time according to the first physical value and the second physical value through a reliability evaluation; storing evaluation result information indicating the deterioration value in a storage unit; retrieving the evaluation result information from the storage unit; dividing the deterioration value indicated as the evaluation result information thus retrieved into a plurality of continuous regions with a value of a predetermined range from a minimum deterioration value to a maximum deterioration value to obtain divided deterioration values; dividing the first physical value into a plurality of continuous regions with a value of a predetermined range; dividing the second physical value into a plurality of continuous regions with a value of a predetermined range; and displaying the divided deterioration values on a display unit as a table representing different states of the divided deterioration values according to the continuous regions of the first physical value and the continuous regions of the second physical value.

As described above, in the second aspect of the present invention, the method of displaying the evaluation result includes the steps of: dividing the deterioration value indicated as the evaluation result information thus retrieved into the continuous regions with the value of the predetermined range from the minimum deterioration value to the maximum deterioration value to obtain the divided deterioration values; dividing the first physical value into the continuous regions with the value of the predetermined range; dividing the second physical value into the continuous regions with the value of the predetermined range; and displaying the divided deterioration values on the display unit as the table representing the different states of the divided deterioration values according to the continuous regions of the first physical value and the continuous regions of the second physical value. Accordingly, it is possible to easily determine whether the semiconductor integrated circuit thus designed possesses desired reliability with time.

According to a third aspect of the present invention, in the method of displaying the evaluation result in the second aspect of the present invention, the different states may be displayed as patterns or colors. Accordingly, it is possible to determine whether the semiconductor integrated circuit thus designed possesses desired reliability with time easily and clearly.

According to a fourth aspect of the present invention, in the method of displaying the evaluation result in the second aspect of the present invention, at least one of the first physical value and the second physical value may include at least one of a gate length of the transistor, a gate width of the transistor, and a drain voltage to be applied to a drain electrode of the transistor. Accordingly, it is possible to easily confirm the deterioration value of the reliability of the transistor with time according to at least one of the gate length of the transistor, the gate width of the transistor, and the drain voltage to be applied to the drain electrode of the transistor.

According to a fifth aspect of the present invention, in the method of displaying the evaluation result in the second aspect of the present invention, at least one of the first physical value and the second physical value may include at least one of a gate voltage to be applied to a gate electrode of the transistor and a temperature of the transistor. Accordingly, it is possible to easily confirm the deterioration value of the reliability of the transistor with time according to at least one of the gate voltage to be applied to the gate electrode of the transistor and the temperature of the transistor.

According to a sixth aspect of the present invention, in the method of displaying the evaluation result in the second aspect of the present invention, the deterioration value of reliability of the transistor with time is measured through a plurality of reliability evaluations having different ratios of periods of time during which the transistor is turned on relative to a specific period of time. The evaluation result information indicating the deterioration values thus measured is stored in the storage unit, so that the table is displayed on the display unit according to the evaluations having the different ratios (duty ratios) of the periods of time during which the transistor is turned on. Accordingly, it is possible to easily confirm the deterioration value of the reliability of the transistor with time according to the evaluations having the different periods of time.

According to a seventh aspect of the present invention, the method of displaying the evaluation result in the second aspect of the present invention further includes the step of calculating at least one of the first physical value and the second physical value smaller than the minimum value according to the evaluation result information. Accordingly, it is possible to easily confirm the first physical value or the second physical value pertaining to a design of the transistor.

According to an eighth aspect of the present invention, an evaluation result display device includes a storage unit for storing evaluation result information indicating a deterioration value of reliability of a transistor with time measured through a reliability evaluation according to a first physical value specified in advance and related to the transistor constituting a semiconductor integrated circuit and a second physical value different from the first physical value while changing the first physical value and the second physical value; a retrieving unit for retrieving the evaluation result information from the storage unit; a display unit for displaying the deterioration value indicated as the evaluation result information retrieved with the retrieving unit as a table representing different states of the deterioration value according to divided deterioration values obtained through dividing the deterioration value into a plurality of continuous regions with a value of a predetermined range from a minimum deterioration value to a maximum deterioration value, and correlating the divided deterioration values to a plurality of continuous regions of the first physical value divided with a value of a predetermined range and a plurality of continuous regions of the second physical value divided with a value of a predetermined range; and a control unit for controlling the display unit to display the table.

As described above, in the eighth aspect of the present invention, the evaluation result display device includes the control unit for controlling the display unit to display the deterioration value indicated as the evaluation result information retrieved with the retrieving unit as the table representing the different states of the deterioration value according to the divided deterioration values obtained through dividing the deterioration value into the continuous regions with the value of the predetermined range from the minimum deterioration value to the maximum deterioration value, and correlating the divided deterioration values to the continuous regions of the first physical value divided with the value of the predetermined range and the continuous regions of the second physical value divided with the value of the predetermined range. Accordingly, it is possible to easily determine whether the semiconductor integrated circuit thus designed possesses desired reliability with time.

As described above, in the present invention, it is possible to easily determine whether the semiconductor integrated circuit thus designed possesses desired reliability with time.

### BRIEF DESCRIPTION OF THE DRAWINGS

FIG. 1 is a schematic block diagram showing a configuration of an electrical system of a reliability evaluation device according to an embodiment of the present invention;

FIG. 2 is a schematic block diagram showing a configuration of an electrical system of a reliability evaluation display device according to the embodiment of the present invention;

FIG. 3 is a flow chart showing an operation of the reliability evaluation device in an evaluation result information storage process according to the embodiment of the present invention;

FIG. 4 is a flow chart showing an operation of the reliability evaluation display device in an evaluation result display process according to the embodiment of the present invention;

FIG. 5 is a schematic view showing an example of an input screen of the reliability evaluation display device according to the embodiment of the present invention;

FIG. 6 is a schematic view showing an example of a monitor screen of the reliability evaluation display device when the reliability evaluation display device displays an evaluation result table of an HCI (Hot Carrier Injection) test according to the embodiment of the present invention;

FIG. 7 is a flow chart showing the operation of the reliability evaluation display device in a design value calculating process according to the embodiment of the present invention;

FIG. 8 is a schematic view showing an example of a design value calculating input screen of the reliability evaluation display device in the design value calculating process according to the embodiment of the present invention; and

FIG. 9 is a schematic view showing an example of the monitor screen of the reliability evaluation display device when the reliability evaluation display device displays an evaluation result table of an NBTI (Negative Bias Temperature Instability) test according to the embodiment of the present invention.

### DETAILED DESCRIPTION OF PREFERRED EMBODIMENTS

Hereunder, preferred embodiments of the present invention will be explained with reference to the accompanying drawings.

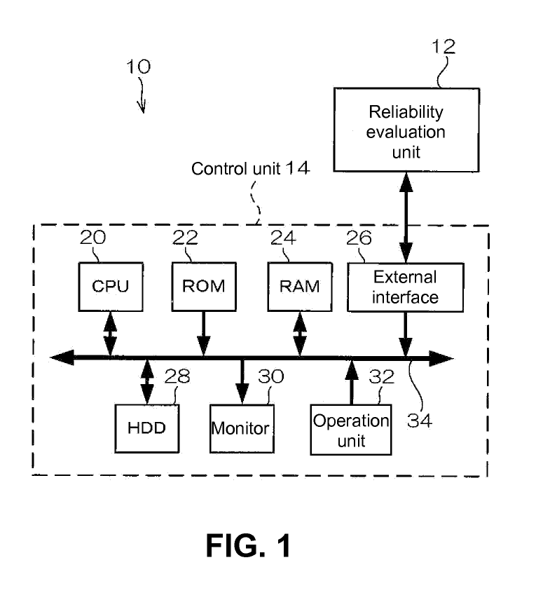

A configuration of a reliability evaluation device 10 will be explained with reference to FIG. 1. FIG. 1 is a schematic block diagram showing the configuration of the electrical system of the reliability evaluation device 10 according to an embodiment of the present invention.

As shown in FIG. 1, the reliability evaluation device 10 includes a reliability evaluation unit 12 and a control unit 14 for controlling the reliability evaluation unit 12. The reliability evaluation unit 12 is provided for performing a reliability evaluation of a transistor constituting a semiconductor integrated circuit. In the reliability evaluation, while a plurality of physical values pertaining to the transistor is varied, a deterioration value of reliability of the transistor with time is measured according to the physical values.

More specifically, the reliability evaluation unit 12 is provided for performing a WLR (Wafer Level Reliability) test using a TEG (Test Element Group) for evaluating the transistor such as a P-channel MOS (Metal Oxide Semiconductor) disposed in a semiconductor wafer. Accordingly, the deterioration value of reliability of the transistor with time is measured.

In the embodiment, the deterioration value of reliability of the transistor with time includes a deterioration value of a property of the transistor from an initial value thereof such as a drain current Ids, a mutual conductance gm, and a threshold voltage Vth. The deterioration value of reliability of the transistor with time is not limited to the values described above, and may further include a deterioration value from an initial value pertaining to other properties of the transistor.

In the embodiment, when the reliability evaluation unit 12 performs the WLR test, the reliability evaluation unit 12 performs an HCI (Hot Carrier Injection) test and an NBTI (Negative Bias Temperature Instability) test. In the HCI test, a drain voltage Vd greater than a gate voltage Vg is applied to a drain electrode of the transistor, so that a change in the property of the transistor is evaluated. In the NBTI test, a negative bias is applied to a gate electrode of the transistor, so that a change in the property of the transistor is evaluated.

In the embodiment, in the reliability evaluation device 10, when the reliability evaluation unit 12 performs the HCI test as the WLR test, the physical value may include at least one of a gate length of the transistor, a gate width of the transistor, and the drain voltage applied to the drain electrode of the transistor. When the reliability evaluation unit 12 performs the HCI test as the WLR test, the physical value may include at least one of the gate voltage applied to the gate electrode of the transistor and a temperature of the transistor. The physical value is not limited to the values described above, and may include other physical values as far as the physical values are related to the transistor.

In the embodiment, in the reliability evaluation device 10, the reliability evaluation unit 12 is further capable of performing a plurality of reliability evaluations having different ratios (duty ratios) of periods of time during which the transistor is turned on relative to a specific period of time.

In the embodiment, the control unit 14 includes a CPU (Central Processing Unit) 20 for controlling an entire operation of the reliability evaluation device 10; an ROM (Read Only Memory) 22 for storing various control programs and various parameters in advance; an RAM (Random Access Memory) 24 used as a work area when the CPU 20 executes the various control programs; an external interface 26 connected to the reliability evaluation unit 12 and an evaluation result display device 40 (described later) for transmitting and receiving various types of information to and from other units such as the reliability evaluation unit 12 and the evaluation result display device 40; an HDD (Hard Disk Drive) 28 functioning as a storage unit for storing the various types of information; a monitor 30 for displaying the various types of information; and an operation unit 32 having a keyboard and a mouse for inputting the various types of information.

In the embodiment, a system bus 34 is provided for mutually and electrically connecting the CPU 20, the ROM 22, the RAM 24, the HDD 28, the monitor 30, the operation unit 32, and the external interface 26. Accordingly, the CPU 20 is capable of accessing to the ROM 22, the RAM 24, and the HDD 28, displaying the various types of information on the monitor 30, retrieving the various types of information through the operation unit 32, and transmitting and receiving the various types of information to and from other units such as the reliability evaluation unit 12 and the evaluation result display device 40 through the external interface 26.

In the embodiment, when the reliability evaluation unit 12 performs the reliability evaluation to obtain the deterioration value of reliability of the transistor with time, the control unit 14 divides the deterioration value of the reliability of the transistor thus measured through the reliability evaluation into a plurality of continuous regions with a value of a predetermined range from a minimum deterioration value to a maximum deterioration value to obtain divided deterioration values. Further, the control unit 14 divides a first physical value into a plurality of continuous regions with a value of a predetermined range, and divides a second physical value into a plurality of continuous regions with a value of a predetermined range. Still further, the control unit 14 stores the divided deterioration values in the HDD 28 according to the continuous regions of the first physical value and the continuous regions of the second physical value.

For example, the minimum deterioration value may be set to 0%, and the maximum deterioration value may be set to 100%. In this case, the control unit 14 divides the deterioration value of the reliability of the transistor into the continuous regions of smaller than 1%, between 1% and 5%, between 5% and 10%, and greater than 10% to obtain the divided deterioration values.

Further, when the reliability evaluation unit 12 of the reliability evaluation device 10 performs the HCI test, the first physical value may be the drain voltage and the second physical value may be the gate length. In this case, the drain voltage may be divided into the continuous regions per 0.1 V, and the gate length may be divided into the continuous regions per 0.1 μm.

In the embodiment, when the reliability evaluation unit 12 performs the reliability evaluations having the different duty ratios, the control unit 14 stores evaluation results in the HDD 28 according to the reliability evaluations having the different duty ratios.

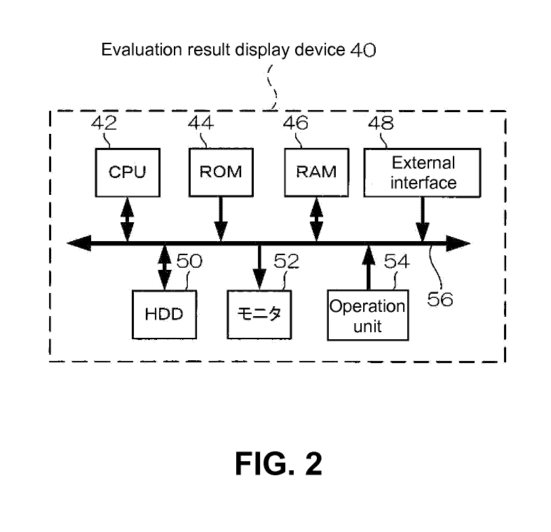

A configuration of an electrical system of the reliability evaluation display device 40 will be explained next with reference to FIG. 2. FIG. 2 is a schematic block diagram showing the configuration of the electrical system of the reliability evaluation display device 40 according to the embodiment of the present invention.

As shown in FIG. 2, the evaluation result display device 40 includes a CPU (Central Processing Unit) 42 for controlling an entire operation of the evaluation result display device 40; an ROM (Read Only Memory) 44 for storing various control programs and various parameters in advance: an RAM (Random Access Memory) 46 used as a work area when the CPU 42 executes the various control programs; an external interface 48 connected to the control unit 14 of the reliability evaluation device 10 for transmitting and receiving the various types of information to and from the control unit 14; an HDD (Hard Disk Drive) 50 functioning as a storage unit for storing the various types of information; a monitor 52 for displaying the various types of information; and an operation unit 54 having a keyboard and a mouse for inputting the various types of information.

In the embodiment, a system bus 56 is provided for mutually and electrically connecting the CPU 42, the ROM 44, the RAM 46, the HDD 50, the monitor 32, the operation unit 54, and the external interface 48. Accordingly, the CPU 42 is capable of accessing to the ROM 44, the RAM 46, and the HDD 50, displaying the various types of information on the monitor 52, retrieving the various types of information through the operation unit 54, and transmitting and receiving the various types of information to and from other units such as the reliability evaluation device 10 through the external interface 48.

In the embodiment, the evaluation result display device 40 is provided for receiving evaluation result information from the control unit 14 of the reliability evaluation device 10 through the external interface 48, and stores the evaluation result information thus received in the HDD 50.

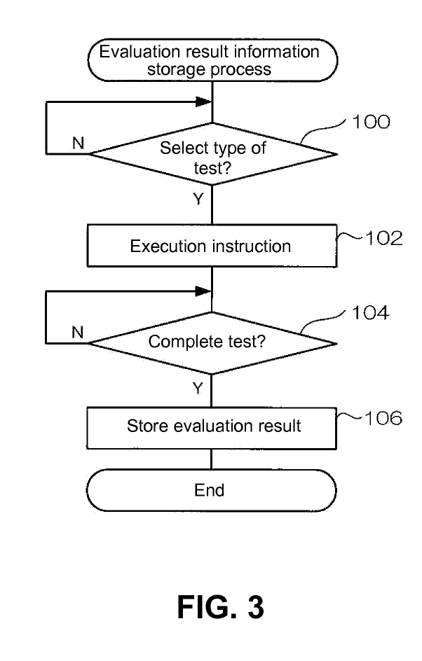

An operation of the control unit 14 of the reliability evaluation device 10 will be explained next with reference to FIG. 3. FIG. 3 is a flow chart showing the operation of the control unit 14 of the reliability evaluation device 10 in an evaluation result information storage process according to the embodiment of the present invention. In the evaluation result information storage process, when a start instruction of the WLR test is input in the reliability evaluation device 10, the CPU 20 executes a program of the evaluation result information storage process through the operation represented with the flow chart shown in FIG. 3. The program is stored in a specific area of the ROM 22 in advance.

As shown in FIG. 3, in step 100, the control unit 14 of the reliability evaluation device 10 becomes an idle state until a type of test is selected. As described above, the reliability evaluation device 10 is capable of performing the HCI test and the NBTI test as the WLR test. Accordingly, a user of the reliability evaluation device 10 selects one of the HCI test and the NBTI test through the operation unit 32. Further, the user inputs a parameter through the operation unit 32 for executing the test thus selected.

In step 102, the type of test, the parameter, and execution instruction information indicating an execution instruction of the test thus selected are transmitted to the reliability evaluation unit 12. When the reliability evaluation device 10 receives the execution instruction information, the reliability evaluation device 10 executes the test thus selected and indicated with the execution instruction information.

In step 104, the control unit 14 of the reliability evaluation device 10 becomes the idle state until the reliability evaluation unit 12 completes the test. In step 106, when the control unit 14 receives the evaluation result from the reliability evaluation unit 12, the control unit 14 stores the evaluation result in the HDD 28 as the evaluation result information, thereby completing the evaluation result information storage process.

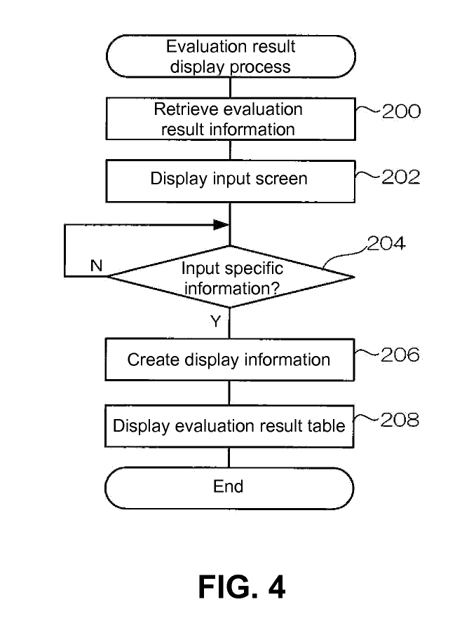

An operation of the reliability evaluation display device 40 will be explained next with reference to FIGS. 4 to 9. In the following description, it is supposed that the reliability evaluation device 10 obtains the evaluation result information through the HCI test, and the evaluation result information is stored in the HDD 50 of the evaluation result display device 40.

In the embodiment, the reliability evaluation display device 40 performs an evaluation result display process, in which the evaluation result represented with the evaluation result information stored in the HDD 50 is displayed on the monitor 50.

The evaluation result display process will be explained next with reference to FIG. 4. FIG. 4 is a flow chart showing the operation of the reliability evaluation display device 40 in the evaluation result display process according to the embodiment of the present invention. In the evaluation result display process, when an execution instruction of the evaluation result display process is input to the evaluation result display device 40, the CPU 42 executes a program of the evaluation result display process through the operation represented with the flow chart shown in FIG. 4. The program is stored in a specific area of the ROM 44 in advance.

In step 200, the evaluation result information is retrieved from the HDD 50. In step 202, an input screen is displayed on the monitor 52 to input specific information, so that the evaluation result represented with the evaluation result information thus retrieved is displayed on the monitor 52. In step 204, the evaluation result display device 40 becomes an idle state until the specific information is input through the input screen.

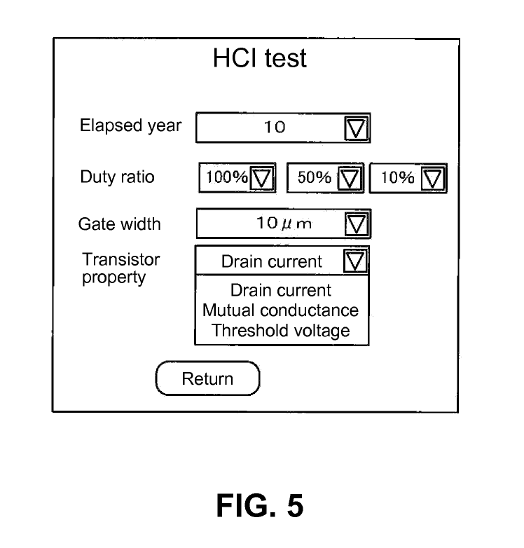

FIG. 5 is a schematic view showing an example of the input screen of the reliability evaluation display device 40 according to the embodiment of the present invention. On the input screen shown in FIG. 5, the evaluation result represented with the evaluation result information obtained through the HCI test is displayed.

In the embodiment, when the input screen is displayed on the monitor 52, the user inputs the specific information including a number of years (an elapsed year) since the transistor has started operating; the duty ratio; the gate width, and the transistor property of at least one of the drain current Ids, the mutual conductance gm, and the threshold voltage Vth. On the input screen shown in FIG. 5, the user can input three types of the duty ratio. The present invention is not limited thereto, and it may be configured such that the user can input less than two types or more than four types of the duty ratio.

As shown in FIG. 5, on the input screen, the elapsed year of 10 years, the duty ratio of 100%, 50%, and 10%, the gate width of 10 μm, and the drain current as the transistor property are input. These values and the transistor property are just an example, and other values and other transistor property may be input.

In the embodiment, the elapsed year, the duty ratio, the gate width, and the transistor property are selected through a pull-down menu, and the present invention is not limited thereto. The elapsed year, the duty ratio, the gate width, and the transistor property may be directly input through a ten-key and the like of the operation unit 54.

In the embodiment, after the user input the specific information, when the user clicks a return button on the input screen or a specific key of the keyboard of the operation unit 54, the evaluation result display process proceeds to step 206.

As described above, the control unit 14 divides the deterioration value of the reliability of the transistor thus measured through the reliability evaluation with the reliability evaluation unit 12 into the continuous regions with the value of the predetermined range from the minimum deterioration value to the maximum deterioration value to obtain the divided deterioration values. Further, the control unit 14 divides the first physical value into the continuous regions with the value of the predetermined range, and divides the second physical value into the continuous regions with the value of the predetermined range. Still further, the control unit 14 stores the divided deterioration values as the evaluation result information in the HDD 28 according to the continuous regions of the first physical value and the continuous regions of the second physical value.

In step 206, the evaluation result display device 40 creates display information according to the specific information thus input, so that an evaluation result table is displayed on the monitor 52. In the evaluation result table, the continuous regions of the deterioration value of reliability of the transistor with time correlate to the continuous regions of the first physical value and the continuous regions of the second physical value. Further, the divided deterioration values are shown in different states in the evaluation result table.

In the embodiment, the minimum deterioration value is set to 0%, and the maximum deterioration value is set to 100%. Accordingly, the control unit 14 divides the deterioration value of the reliability of the transistor into the continuous regions of smaller than 1%, between 1% and 5%, between 5% and 10%, and greater than 10% to obtain the divided deterioration values.

Further, the first physical value is set to be the drain voltage, and the second physical value is set to be the gate length. In this case, the drain voltage is divided into the continuous regions per 0.1 V, and the gate length is divided into the continuous regions per 0.1 μm. The evaluation result is shown in an evaluation result table, in which the deterioration value of the drain current Ids is represented with different patterns according to the divided deterioration values.

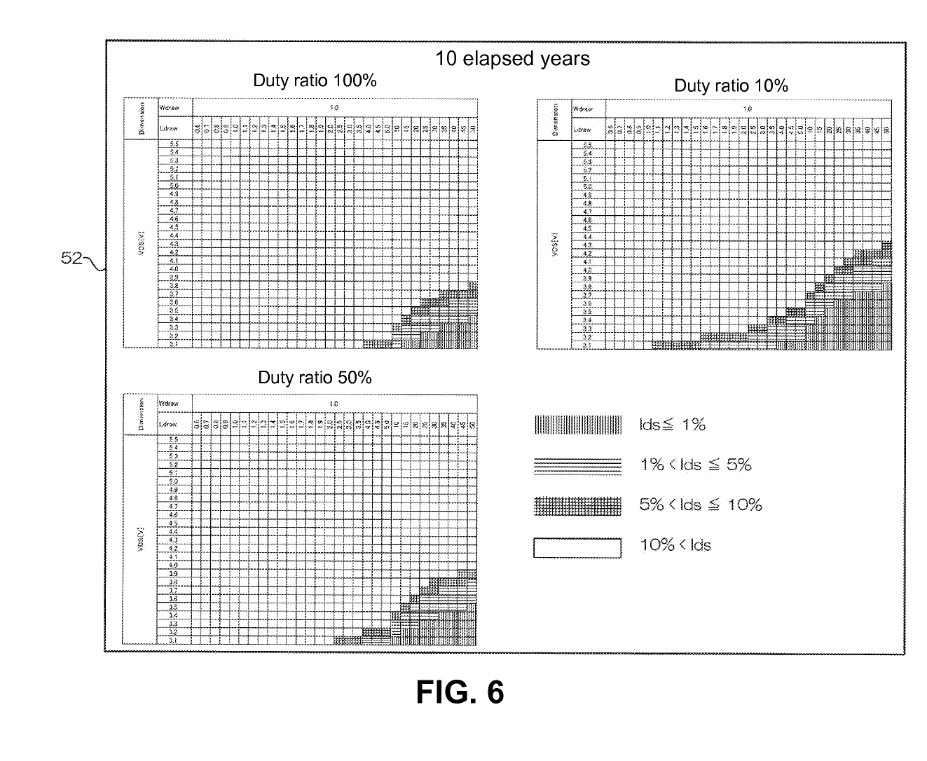

FIG. 6 is a schematic view showing an example of the monitor screen of the reliability evaluation display device 40 when the reliability evaluation display device 40 displays the evaluation result table of the HCI (Hot Carrier Injection) test according to the embodiment of the present invention.

As shown in FIG. 6, as an example of the patterns, when the deterioration value of the drain current Ids is less than 1%, a section is represented with a vertical stripe pattern. When the deterioration value of the drain current Ids is between 1% and 5%, a section is represented with a lateral stripe pattern. When the deterioration value of the drain current Ids is between 5% and 10%, a section is represented with a mesh pattern. When the deterioration value of the drain current Ids is greater than 10%, a section is represented without a pattern. The present invention is not limited thereto, and other patterns may be used.

In the embodiment, in the evaluation result display device 40, the deterioration value of the drain current Ids is represented with the different patterns according to the divided deterioration values. The present invention is not limited thereto, and the deterioration value of the drain current Ids may be represented with different colors according to the divided deterioration values.

When the deterioration value of the drain current Ids is represented with different colors according to the divided deterioration values, for example, when the deterioration value of the drain current Ids is less than 1%, a section is represented in green. When the deterioration value of the drain current Ids is between 1% and 5%, a section is represented in yellow. When the deterioration value of the drain current Ids is between 5% and 10%, a section is represented in red. When the deterioration value of the drain current Ids is greater than 10%, a section is represented in white. The present invention is not limited thereto, and other colors may be used.

In step 208, the evaluation result table is displayed on the monitor according to the display information created in step 206, thereby completing the evaluation result display process.

As described above, the evaluation result table indicating the evaluation result of the duty ratio of 100%, 50%, and 10% at the elapsed year of 10 years is displayed on the monitor 52 according to the specific information input through the input screen shown in FIG. 5.

In the embodiment, the evaluation result table shows the deterioration value of the drain current Ids at the gate width (Wdraw) of 10 μm. Further, in the evaluation result table, the vertical axis and the horizontal axis represent the physical values pertaining to the transistor property. More specifically, the horizontal axis represents the gate length (Ldraw), and the vertical axis represents the drain voltage (Vds).

Further, according to the gate length (Ldraw) and the drain voltage (Vds), the deterioration value of the drain current Ids is represented with the different patterns according to the continuous regions of smaller than 1%, between 1% and 5%, between 5% and 10%, and greater than 10%.

In the embodiment, the evaluation result display device 40 further performs a design value calculating process to calculate a physical value pertaining a design of the transistor, that is a design value of the transistor (such as the gate length and the gate width) smaller than the deterioration value input by the user in advance according to the evaluation result information stored in the HDD 50.

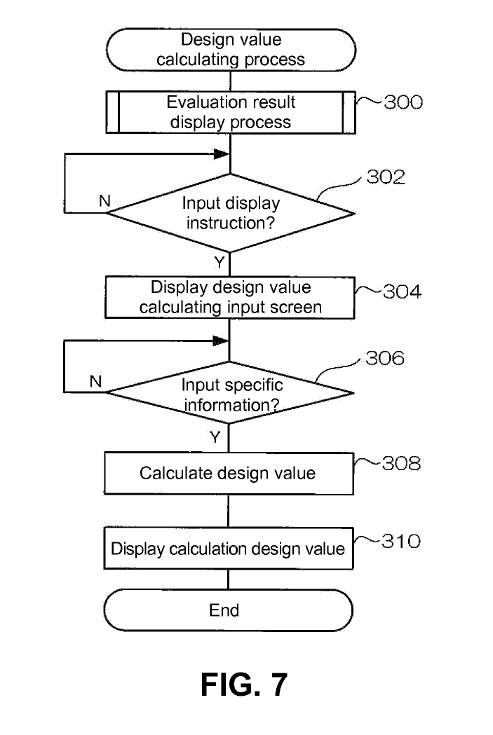

The design value calculating process will be explained next with reference to FIG. 7. FIG. 7 is a flow chart showing the operation of the reliability evaluation display device 40 in the design value calculating process according to the embodiment of the present invention. In the design value calculating process, when an execution instruction of the design value calculating process is input to the evaluation result display device 40, the CPU 42 executes a program of the design value calculating process through the operation represented with the flow chart shown in FIG. 7. The program is stored in a specific area of the ROM 44 in advance.

In step 300, the evaluation result display process is performed. In step 302, the evaluation result display device 40 becomes the idle state until the user clicks a specific button displayed on the monitor 52 or a specific key of the keyboard of the operation unit 54, so that a display instruction is input to display a design value calculating input screen for inputting specific information necessary for calculating the design value.

In step 304, the design value calculating input screen is displayed on the monitor 52. In step 306, the evaluation result display device 40 becomes the idle state until the specific information is input through the design value calculating input screen.

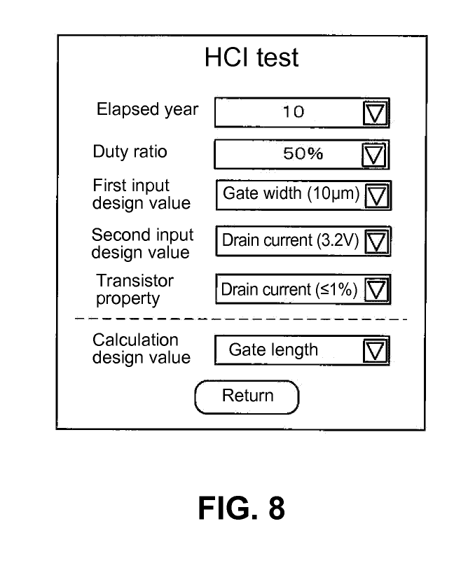

FIG. 8 is a schematic view showing an example of the design value calculating input screen of the reliability evaluation display device 40 in the design value calculating process according to the embodiment of the present invention. On the design value calculating input screen shown in FIG. 8, the design value is calculated according to the evaluation result information obtained through the HCI test.

In the embodiment, when the design value calculating input screen is displayed on the monitor 52, the user inputs the specific information such as the elapsed year; the duty ratio; a first input design value; a second input design value; the deterioration value of the transistor property; and a calculation design value.

Accordingly, in the design value calculating process, the design value is calculated according to the elapsed year; the duty ratio; the first input design value; the second input design value; and the deterioration value of the transistor property.

As shown in FIG. 8, on the design value calculating input screen, the elapsed year of 10 years, the duty ratio of 50%, the gate width of 10 μm as the first input design value, the drain voltage of 3.2 V as the second input design value, the drain current with the deterioration value less than 1% as the transistor property, and the gate length as the calculation design value are input. These values and the transistor property are just an example, and other values and other transistor property may be input.

In the embodiment, the elapsed year, the duty ratio, the first input design value, the second input design value, the deterioration value of the transistor property, and the calculation design value are selected through a pull-down menu, and the present invention is not limited thereto. The elapsed year, the duty ratio, the first input design value, the second input design value, the deterioration value of the transistor property, and the calculation design value may be directly input through the ten-key and the like of the operation unit 54.

In the embodiment, on the design value calculating input screen shown in FIG. 8, the user can input three types of the input design value, i.e., the first input design value, the second input design value. The present invention is not limited thereto, and it may be configured such that the user can change the combination such as one type of the input design value and two types of the calculation design value.

In the embodiment, after the user input the specific information, when the user clicks a return button on the design value calculating input screen or a specific key of the keyboard of the operation unit 54, the design value calculating process proceeds to step 308.

In step 308, according to the specific information thus input on the design value calculating input screen, the design value is calculated.

For example, on the design value calculating input screen shown in FIG. 8, the elapsed year of 10 years, the duty ratio of 50%, the gate width of 10 μm as the first input design value, the drain voltage of 3.2 V as the second input design value, and the drain current with the deterioration value less than 1% as the transistor property are input. Accordingly, the gate length of 15 μm to 50 μm is calculated as the calculation design value.

In step 310, the calculation design value thus calculated on the monitor 52, thereby completing the design value calculating process. Accordingly, the user can easily confirm the calculation design value pertaining to the design of the transistor.

As described above, in the embodiment, the reliability evaluation unit 12 is provided for performing the reliability evaluation, in which while the gate length and the drain voltage of the transistor constituting the semiconductor integrated circuit are varied, the deterioration value of reliability of the transistor with time is measured according to the gate length and the drain voltage of the transistor. Accordingly, it is possible to obtain the evaluation result information indicating the deterioration value of reliability of the transistor.

Further, the evaluation result information indicating the deterioration value of reliability of the transistor with time is stored in the HDD 50. As described above, the control unit 14 divides the deterioration value of the reliability of the transistor thus measured through the reliability evaluation with the reliability evaluation unit 12 into the continuous regions with the value of the predetermined range from the minimum deterioration value to the maximum deterioration value to obtain the divided deterioration values. Further, the control unit 14 divides the first physical value into the continuous regions with the value of the predetermined range, and divides the second physical value into the continuous regions with the value of the predetermined range.

In the embodiment, the evaluation result information is retrieved from the HDD 50, so that the evaluation result table is displayed on the monitor 52. In the evaluation result table, the continuous regions of the deterioration value of reliability of the transistor with time correlate to the continuous regions of the first physical value and the continuous regions of the second physical value. Further, the divided deterioration values are shown in different states in the evaluation result table. Accordingly, it is possible to easily confirm reliability of the semiconductor integrated circuit.

Further, the evaluation result information is stored in the HDD 50 according to the reliability evaluations with the different duty ratios of the transistor. The evaluation result table is displayed on the monitor 52 according to the reliability evaluations with the different duty ratios of the transistor. Accordingly, it is possible to confirm the deterioration value of reliability of the transistor according to the different duty ratios.

As described above, the embodiment of the present invention is explained, and the present invention is not limited to the embodiment.

In the embodiment described above, in the evaluation result table indicating the evaluation result of the HCI test, the horizontal axis represents the gate length (Ldraw) of the transistor and the vertical axis represents the drain voltage (Vds) of the transistor, while the gate width is maintained at the fixed value. The present invention is not limited thereto. The evaluation result table may have other configurations such that, for example, the horizontal axis represents the gate length (Ldraw) of the transistor and the vertical axis represents the gate width of the transistor, while the drain voltage (Vds) may be maintained at a fixed value. Further, the evaluation result table may have a configurations such that the horizontal axis and the vertical axis representing physical values of the transistor specified by the user.

Further, in the embodiment described above, the evaluation result table indicating the result of the HCI test is displayed on the monitor 52. The present invention is not limited thereto, and the evaluation result table indicating the evaluation result of the NBTI test may be displayed on the monitor 52.

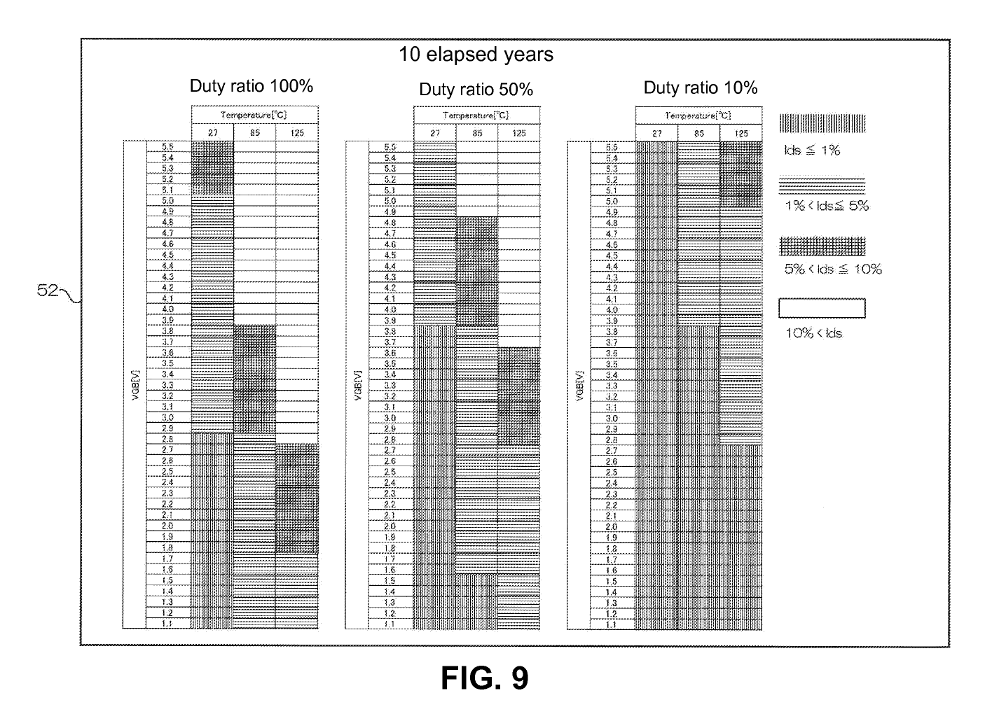

FIG. 9 is a schematic view showing an example of the monitor screen of the reliability evaluation display device 40 when the reliability evaluation display device 40 displays the evaluation result table of the NBTI (Negative Bias Temperature Instability) test according to the embodiment of the present invention.

As shown in FIG. 9, the evaluation result table indicates the evaluation result of the NBTI test with the duty ratios of 100%, 50%, and 10%. Further, the evaluation result table indicates the deterioration value of the drain current Ids at the elapsed year of 10 years. In the evaluation result table, the horizontal axis represents the temperature (° C.) of the transistor and the vertical axis represents the gate voltage (Vgd) of the transistor.

Further, in the embodiment described above, the evaluation result display device 40 performs the evaluation result display process and the design value calculating process. The present invention is not limited thereto. It may be configured such that the control unit 14 of the reliability evaluation device 10 performs the evaluation result display process and the design value calculating process. In the configuration, a program is stored in a specific area of the ROM 20 of the control unit 14 in advance for performing the evaluation result display process and the design value calculating process.

Further, in the embodiment described above, the reliability evaluation device 10 performs the HCI test and the NBTI test. The present invention is not limited thereto. It may be configured such that the reliability evaluation device 10 performs other tests such as a TDDB (Time Dependent Dielectric Breakdown) test and a PBTI (Positive Bias Temperature Instability) test relative to an n-channel MOS transistor.

The disclosure of Japanese Patent Application No. 2010-006957, filed on Jan. 15, 2010, is incorporated in the application by reference.

While the invention has been explained with reference to the specific embodiments of the invention, the explanation is illustrative and the invention is limited only by the appended claims.

What is claimed is:

1. A method of storing an evaluation result comprising the steps of:
changing a first physical value specified in advance and related to a transistor constituting a semiconductor integrated circuit;
changing a second physical value different from the first physical value;
measuring a deterioration value of reliability of the transistor with time according to the first physical value and the second physical value through a reliability evaluation;
dividing the deterioration value into a plurality of first continuous regions with a first value from a minimum deterioration value to a maximum deterioration value to obtain divided deterioration values;
dividing the first physical value into a plurality of second continuous regions with a second value;
dividing the second physical value into a plurality of third continuous regions with a third value; and
storing the divided deterioration values in a storage unit according to the first continuous regions and the second continuous regions.

2. A method of displaying an evaluation result, comprising the steps of:
changing a first physical value specified in advance and related to a transistor constituting a semiconductor integrated circuit;
changing a second physical value different from the first physical value;
measuring a deterioration value of reliability of the transistor with time according to the first physical value and the second physical value through a reliability evaluation;
storing evaluation result information indicating the deterioration value in a storage unit;
retrieving the evaluation result information from the storage unit;
dividing the deterioration value into a plurality of first continuous regions with a first value from a minimum deterioration value to a maximum deterioration value to obtain divided deterioration values;
dividing the first physical value into a plurality of second continuous regions with a second value;
dividing the second physical value into a plurality of third continuous regions with a third value; and
displaying the divided deterioration values on a display unit as a table representing different states of the divided deterioration values according to the second continuous regions and the third continuous regions.

3. The method of displaying the evaluation result according to claim 2, wherein, in the step of displaying the divided deterioration values on the display unit as the table representing the different states of the divided deterioration values, said different states are displayed as patterns or colors.

4. The method of displaying the evaluation result according to claim 2, wherein, in the steps of changing the first physical value and changing the second physical value, at least one of said first physical value and said second physical value includes at least one of a gate length of the transistor, a gate width of the transistor, and a drain voltage to be applied to a drain electrode of the transistor.

5. The method of displaying the evaluation result according to claim 2, wherein, in the steps of changing the first physical value and changing the second physical value, at least one of said first physical value and said second physical value includes at least one of a gate voltage to be applied to a gate electrode of the transistor and a temperature of the transistor.

6. The method of displaying the evaluation result according to claim 2, wherein, in the steps of measuring the deterioration value of the reliability of the transistor with time, said deterioration value is measured through a plurality of reliability evaluations having different ratios of periods of time during which the transistor is turned on relative to a specific period of time, and said evaluation result information is stored in the storage unit so that the table is displayed on the display unit according to the evaluations having the different ratios.

7. The method of displaying the evaluation result according to claim 2, further comprising the step of calculating at least one of the first physical value and the second physical value smaller than the minimum value according to the evaluation result information.

8. An evaluation result display device, comprising:
a storage unit for storing evaluation result information indicating a deterioration value of reliability of a transistor with time measured through a reliability evaluation according to a first physical value specified in advance and related to the transistor constituting a semiconductor integrated circuit and a second physical value different from the first physical value while changing the first physical value and the second physical value;
a retrieving unit for retrieving the evaluation result information from the storage unit;
a display unit for displaying the deterioration value indicated as the evaluation result information as a table representing different states of the deterioration value according to divided deterioration values obtained through dividing the deterioration value into a plurality of continuous regions with a value of a predetermined range from a minimum deterioration value to a maximum deterioration value, and correlating the divided deterioration values to a plurality of continuous regions of the first physical value divided with a value of a predetermined range and a plurality of continuous regions of the second physical value divided with a value of a predetermined range; and
a control unit for controlling the display unit to display the table.
